(19) United States
(12) Patent Application Publication
(10) Pub. No.: US 2003/0237039 A1
(43) Pub. Date: Dec. 25, 2003

(54) Apparatus and method for a table-lookup device

(75) Inventor: Sigang Qiu, Raleigh, NC (US)

Correspondence Address: Pillsbury Winthrop LLP, Intellectual Property Group, Suite 2800, 725 South Figueroa Street, Los Angeles, CA, 90017-5406, US

(73) Assignee: Intel Corporation, Santa Clara, CA

(21) Appl. No.: 10/178,280

(22) Filed: Jun. 24, 2002

(51) Int. Cl. H03M 13/00

(52) U.S. Cl. 714/758

(57) ABSTRACT

A table-lookup device includes an input to receive a plurality of data bits. A first combiner is included to combine a generator polynomial and a known polynomial and to provide an auxiliary generator polynomial. A data table array is based on the auxiliary generator polynomial. A memory is included to store the data table array. A second combiner is included to combine the plurality of data bits and the auxiliary generator polynomial and to provide a table array index. The table array index indicates an address of an element of the data table array.

### BACKGROUND

1. Technical Field

An embodiment of the present invention generally relates to a table-lookup device. More particularly, an embodiment of the present invention relates to a table-lookup device for a communication application.

2. Discussion of the Related Art

A cyclic redundancy check (“CRC”) device, a scrambler device, and a de-scrambler device are three key components in modern telecommunication devices. In fact, most telecommunication products that are currently available, including modems and a variety of Internet products, have a CRC device and a scrambler device and/or a de-scrambler device. A CRC device generally provides a group of bits, known as a CRC value, that may be appended to the end of a message (or frame) to ensure proper and reliable information transmission. A transmitter often includes a CRC device for this reason. A receiver, for instance, may generate a CRC value, so that the generated CRC value can be compared to the CRC value that is received from the transmitter. If the two CRC values are same, then it is very unlikely that the data was corrupted during transmission. A message polynomial may be created from a stream of data bits. The CRC value is usually created by dividing the message polynomial by a generator polynomial. The remainder of this operation generally represents the CRC value. Some commonly used examples of generator polynomials are g(D)=D¹⁶+D¹⁵+D²+1, representing CRC-16, for example, and g(D)=D³²+D²⁶+D²³+D²²+D¹⁶+D¹²+D¹¹+D¹⁰+D⁸+D⁷+D⁵+D⁴+D²+D+1, representing Ethernet, for example, where “D” may represent a delay. The CRC-16 generator polynomial in the example above is described in the pre-published G.991.2 standard, ITU-T G.991.2, February 2001, which describes a transmission method for data transport in telecommunications access networks. The Ethernet generator polynomial in the example above is described in the 802.3 standard, IEEE 802.3-2002, published Mar. 8, 2002, which describes media access control characteristics for the Carrier Sense Multiple Access with Collision Detection (“CSMA/CD”) access method for shared medium local area networks.

Although a scrambler device typically divides a message polynomial by a generator polynomial, the scrambler device generally does not append the end of a message with additional data bits. Rather, the message itself is typically “scrambled” and transmitted in its scrambled form. The purpose of the scrambler device is to randomize data and whiten the spectrum, thereby facilitating synchronization of the message. In other words, the scrambler device may cause the spectrum of the data to be flat, for example.

Communication devices and systems continue to be designed with ever-increasing processing capabilities; however, current technologies, such as digital signal processors (“DSPs”), have placed upper limits on hardware device capabilities and system processing speeds. Conventional CRC devices, for example, require extensive use of DSPs. Thus, a method has been proposed to increase the processing speed with which a CRC value may be calculated. In T. V. Ramabadran and S. S. Gaitonde, “A Tutorial on CRC Computations,” IEEE Micro, August 1988, pp. 62-74 (“the Ramabadran reference”), a table lookup algorithm is specified, such that the CRC value corresponding to a particular bit stream segment may be stored in a table, thereby reducing the complexity of the CRC calculation. The bit stream segment utilized in the Ramabadran reference is a group of eight bits. The generator polynomial may be used to obtain the address of the element of the table that corresponds to a value that may be manipulated to obtain the CRC value. However, this technique is applicable only to a CRC device, and not a scrambler device nor a de-scrambler device. Furthermore, this technique requires that the order of the generator polynomial be a multiple of eight.

### BRIEF DESCRIPTION OF THE DRAWINGS

FIG. 1 illustrates a table-lookup device according to an embodiment of the present invention;

FIG. 2 illustrates a transmitting communication device according to an embodiment of the present invention;

FIG. 3 illustrates a receiving communication device according to an embodiment of the present invention;

FIG. 4 illustrates a block diagram of a communication system according to an embodiment of the present invention;

FIG. 5 illustrates a flow chart for a method of processing data according to an embodiment of the present invention;

FIG. 6 illustrates a flow chart for a method of processing CRC data according to an embodiment of the present invention;

FIG. 7 illustrates a flow chart for a method of processing scrambler data according to an embodiment of the present invention; and

FIG. 8 illustrates a flow chart for a method of processing de-scrambler data according to an embodiment of the present invention.

### DETAILED DESCRIPTION

Reference in the specification to “one embodiment”, “an embodiment”, or “another embodiment” of the present invention means that a particular feature, structure or characteristic described in connection with the embodiment is included in at least one embodiment of the present invention. Thus, the appearances of the phrase “in one embodiment” or “according to an embodiment” appearing in various places throughout the specification are not necessarily all referring to the same embodiment. Likewise, appearances of the phrase “in another embodiment” or “according to another embodiment” appearing in various places throughout the specification are not necessarily referring to different embodiments.

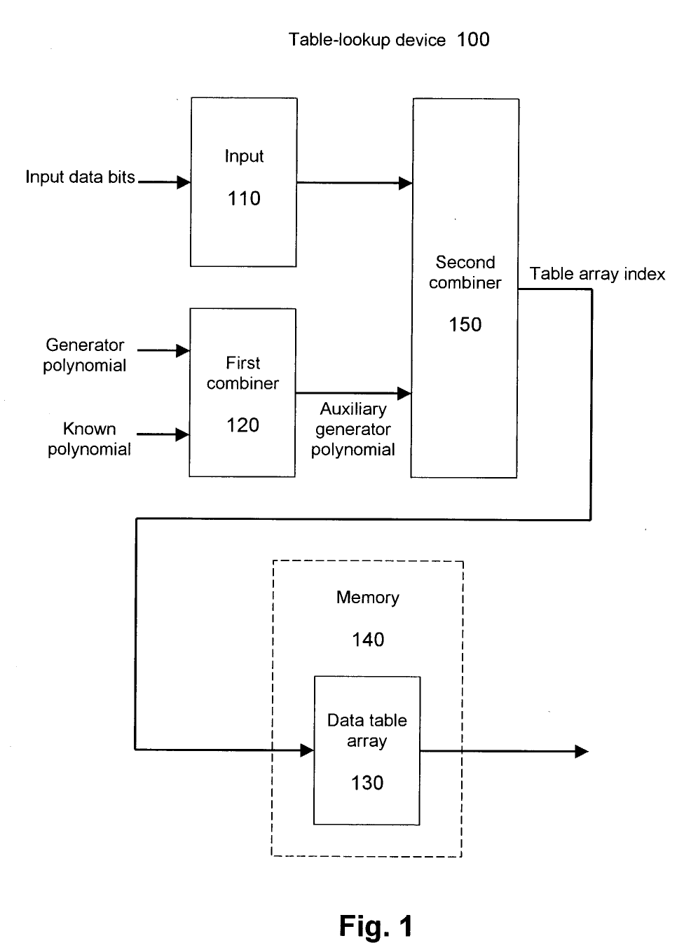

FIG. 1 illustrates a table-lookup device according to an embodiment of the present invention. The table-lookup device 100 includes an input 110, a first combiner 120, a data table array 130, a memory 140, and a second combiner 150. The input 110 receives a plurality of data bits. The plurality of data bits may be a segment of the input data bits, wherein the input data bits represent a stream of data bits that are to be processed. The input data bits need not be a multiple of eight. If the input data bits are not a multiple of eight, but eight-bit processing is desired, then the input data bits may be “padded” with one or more bit zeros to provide a multiple of eight data bits. For example, if the input data bits are thirteen data bits, then the input data bits may be padded with three bit zeros to provide sixteen data bits. However, if the input data bits are not a multiple of eight, and eight-bit processing is not required/desired, then padding the input data bits with one or more zeros may not be necessary. The first combiner 120 combines a generator polynomial and a known polynomial and provides an auxiliary generator polynomial. The data table array 130 is based on the auxiliary generator polynomial. The memory 140 stores the data table array 130. The second combiner 150 combines the plurality of data bits and the auxiliary generator polynomial and provides a table array index. The table array index indicates an address of an element of the data table array 130. The first combiner 120 and/or the second combiner 150 may perform any mathematical and/or logical operation. For example, a mathematical operation may include addition, subtraction, multiplication, and/or division. A logical operation may include, for example, an “and” operation, an “or” operation, a “nand” operation, a “nor” operation, an “exclusive or” operation, and/or an “exclusive nor” operation.

According to an embodiment of the present invention, the first combiner 120 and the second combiner 150 may be a single device. In an embodiment, the table-lookup device 100 may be a cyclic redundancy check (“CRC”) device. For example, the generator polynomial for CRC processing may be g(D)=D⁶+D+1, and the known polynomial may be k(D)=D²+1, where “D” may represent a delay. The generator polynomial and the known polynomial may be combined by performing a polynomial multiplication operation over a Galois field, GF(2), providing an auxiliary generator polynomial of gₐᵤₓ(D)=g(D)\mathring{×}k(D)=D⁸+D⁶+D³+D²+D+1. According to an embodiment, the auxiliary generator polynomial may have an order of a multiple of eight.

In an embodiment, the table-lookup device 100 may be a scrambler device. The table-lookup device 100 may be a de-scrambler device in another embodiment. For example, a scrambler device may employ a first generator polynomial (i.e., a scrambler generator polynomial), which may be, for example, g₁(D)=1+D⁻¹⁸+D⁻²³. A de-scrambler device may employ a second generator polynomial (i.e., a de-scrambler generator polynomial), which may be, for example, g₂(D)=1+D⁻⁵+D⁻²³. The known polynomial may be, for example, k(D)=(1+D⁹)D²³. The first generator polynomial and a known polynomial may be combined by performing a polynomial multiplication operation, providing a first auxiliary generator polynomial of gₐᵤₓ₁(D)=g₁(D)\mathring{×}k(D)=1+D⁵+D⁹+D¹⁴+D²³+D³². The second generator polynomial and a known polynomial may be combined by performing a polynomial multiplication operation, providing a second auxiliary generator polynomial of gₐᵤₓ₂(D)=g₂(D)\mathring{×}k(D)=1+D⁹+D¹⁸+D²³ +D²⁷+D³². The known polynomial that is combined with the first generator polynomial need not be same as the known polynomial that is combined with the second generator polynomial. According to an embodiment, the first auxiliary generator polynomial and/or the second auxiliary generator polynomial may have an order of a multiple of eight. In an embodiment, a number of possible values of the table array index may be a multiple of eight.

An embodiment of the present invention may be used in accordance with a variety of telecommunications standards. For example, it may be used in accordance with the V.90 standard, International Telecommunication Union-T (“ITU-T”) V.90, published Sep. 25, 1998, which specifies the manner in which a digital modem and an analog modem are to communicate under certain situations. It may also be used, for example, in accordance with the G.992.1 standard, ITU-T G.992.1, published Jun. 22, 1999, which describes the manner in which asymmetric digital subscriber line (“ADSL”) transmission is to occur under certain conditions.

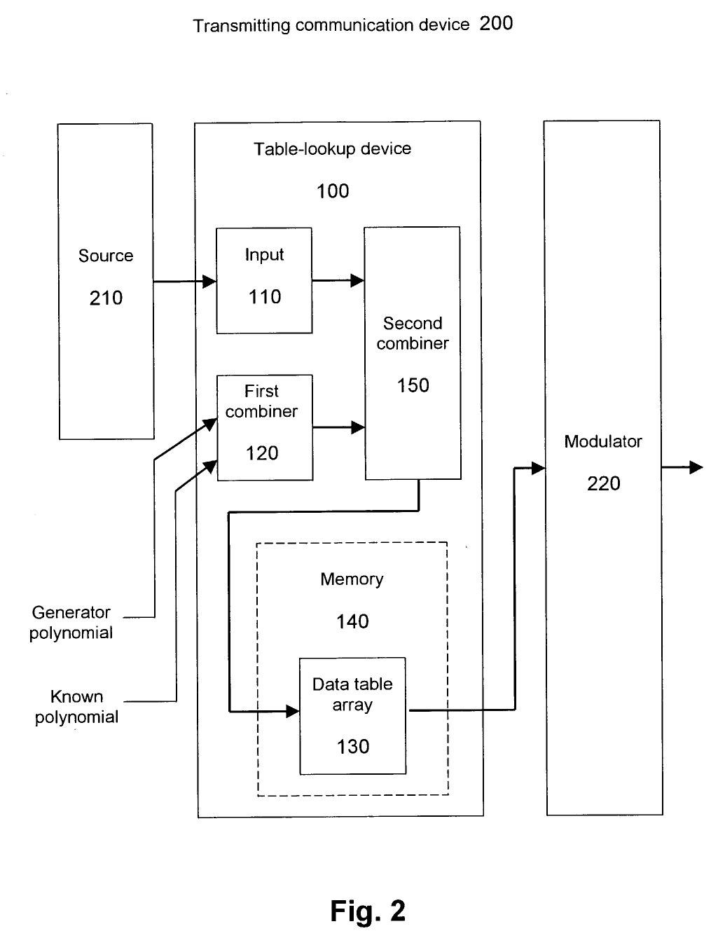

FIG. 2 illustrates a transmitting communication device according to an embodiment of the present invention. The transmitting communication device 200 includes a source 210, a table-lookup device 100, and a modulator 220. The source 210 provides input data bits. The table-lookup device 100 receives the input data bits. The table-lookup device 100 includes an input 110, a first combiner 120, a data table array 130, a memory 140, and a second combiner 150. The input 110 receives a plurality of data bits. The plurality of data bits may be a segment of the input data bits, wherein the input data bits represent a stream of data bits that are to be processed. The first combiner 120 combines a generator polynomial and a known polynomial and provides an auxiliary generator polynomial. The data table array 130 is based on the auxiliary generator polynomial. The memory 140 stores the data table array 130. The second combiner 150 combines the plurality of data bits and the auxiliary generator polynomial and provides a table array index. The table array index indicates an address of an element of the data table array 130. The modulator 220 modulates a symbol that is based on an output of the table-lookup device 100.

According to an embodiment of the present invention, the first combiner 120 and the second combiner 150 may be a single device. In an embodiment, the table-lookup device 100 may be a cyclic redundancy check (“CRC”) device. According to an embodiment, the table-lookup device 100 may be a scrambler device. In an embodiment, the transmitting communication device 200 may be a transmitter. If the table-lookup device 100 is a cyclic redundancy check (“CRC”) device, then an output of the cyclic redundancy check (“CRC”) device may be combined with the input data bits.

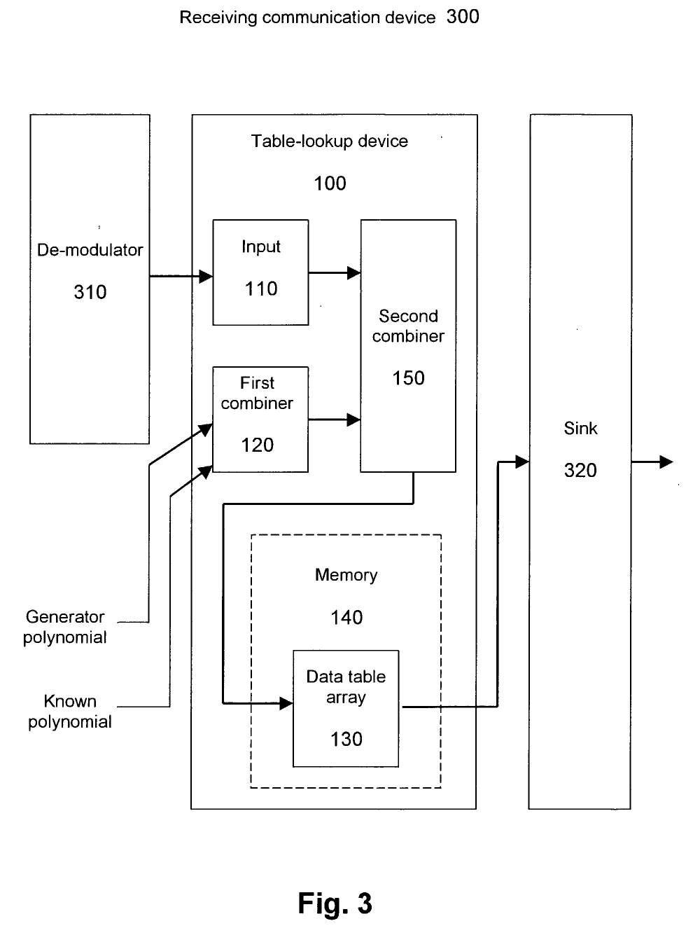

FIG. 3 illustrates a receiving communication device according to an embodiment of the present invention. The receiving communication device 300 includes a demodulator 310, a table-lookup device 100, and a sink 320. The de-modulator 310 demodulates a received symbol. The table-lookup device 100 receives input data bits. The input data bits represent a stream of data bits that are based on the received symbol. The table-lookup device 100 includes an input 110, a first combiner 120, a data table array 130, a memory 140, and a second combiner 150. The input 110 receives a plurality of data bits. The plurality of data bits may be a segment of input data bits. The first combiner 120 combines a generator polynomial and a known polynomial and provides an auxiliary generator polynomial. The data table array 130 is based on the auxiliary generator polynomial. The memory 140 stores the data table array 130. The second combiner 150 combines the plurality of data bits and the auxiliary generator polynomial and provides a table array index. The table array index indicates an address of an element of the data table array 130. The sink 320 stores a stream of data bits. The stream of data bits may be the input data bits. If the table-lookup device 100 is a cyclic redundancy check (“CRC”) device, then a CRC value may be removed from the input data bits.

According to an embodiment of the present invention, the first combiner 120 and the second combiner 150 may be a single device. In an embodiment, the table-lookup device 100 may be a cyclic redundancy check (“CRC”) device. According to an embodiment, the table-lookup device 100 may be a de-scrambler device. In an embodiment, the receiving communication device 300 may be a receiver.

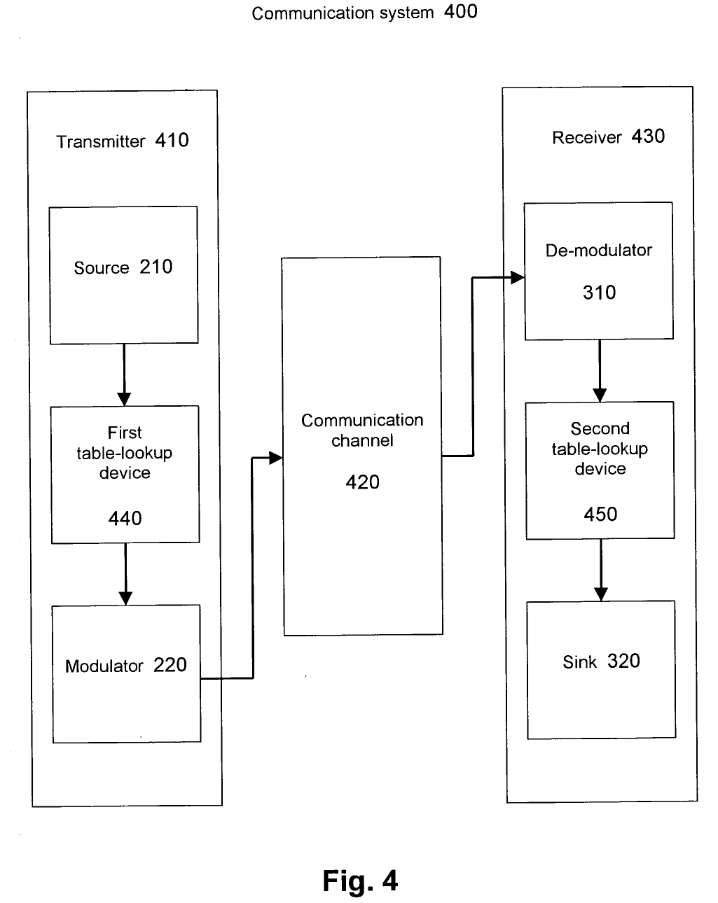

FIG. 4 illustrates a block diagram of a communication system according to an embodiment of the present invention. The communication system 400 includes a transmitter 410, a communication channel 420, and a receiver 430. The transmitter 410 includes a source 210, a first data-lookup device 440, and a modulator 220. The source 210 provides input data bits. The first data-lookup device 440 provides a first auxiliary generator polynomial and provides a first table array index. The first table array index is based on the first auxiliary generator polynomial. The first table array index indicates a first address of a first element of a first data table array. The modulator 220 modulates a symbol that is based on an output of the first table-lookup device 440. The communication channel 420 receives an output of the modulator 220. The receiver 430 receives an output of the communication channel 420. The receiver 430 includes a de-modulator 310, a second table-lookup device 450, and a sink 320. The de-modulator 310 de-modulates a received symbol. The second table-lookup device 450 provides a second auxiliary generator polynomial and provides a second table array index. The second table array index is based on the second auxiliary generator polynomial. The second table array index indicates a second element of a second data table array. The sink 320 stores a stream of data bits. The stream of data bits may be the input data bits.

According to an embodiment of the present invention, the first table-lookup device 440 may include an input 110, a first combiner 120, a memory 140, and a second combiner 150 (see FIG. 2). The input 110 may receive a plurality of data bits. The plurality of data bits may be a segment of the input data bits, wherein the input data bits represent a stream of data bits that are to be processed. The first combiner 120 may combine a generator polynomial and a known polynomial and may provide the first auxiliary generator polynomial. The memory 140 may store the first data table array. The second combiner 150 may combine the plurality of data bits and the first auxiliary generator polynomial and may provide the first table array index.

In an embodiment, the second table-lookup device 450 may include an input 110, a first combiner 120, a memory 140, and a second combiner 150 (see FIG. 3). The input 110 may receive a plurality of data bits. The plurality of data bits may be a segment of the input data bits, wherein the input data bits represent a stream of data bits that are to be processed. The first combiner 120 may combine a generator polynomial and a known polynomial and may provide the second auxiliary generator polynomial. The memory 140 may store the second data table array. The second combiner 150 may combine the plurality of data bits and the second auxiliary generator polynomial and may provide the second table array index.

According to an embodiment, the communication system 400 may be a modem. In an embodiment, the communication system 400 may be a networking system. Examples of a networking system include a local area network (“LAN”) and a wide area network (“WAN”).

The first table-lookup device 440 may be a cyclic redundancy check (“CRC”) device in an embodiment. In another embodiment, the first table-lookup device 440 may be a scrambler device. According to an embodiment, the second table-lookup device 450 may be a cyclic redundancy check (“CRC”) device. In an embodiment, the second table-lookup device 450 may be a de-scrambler device.

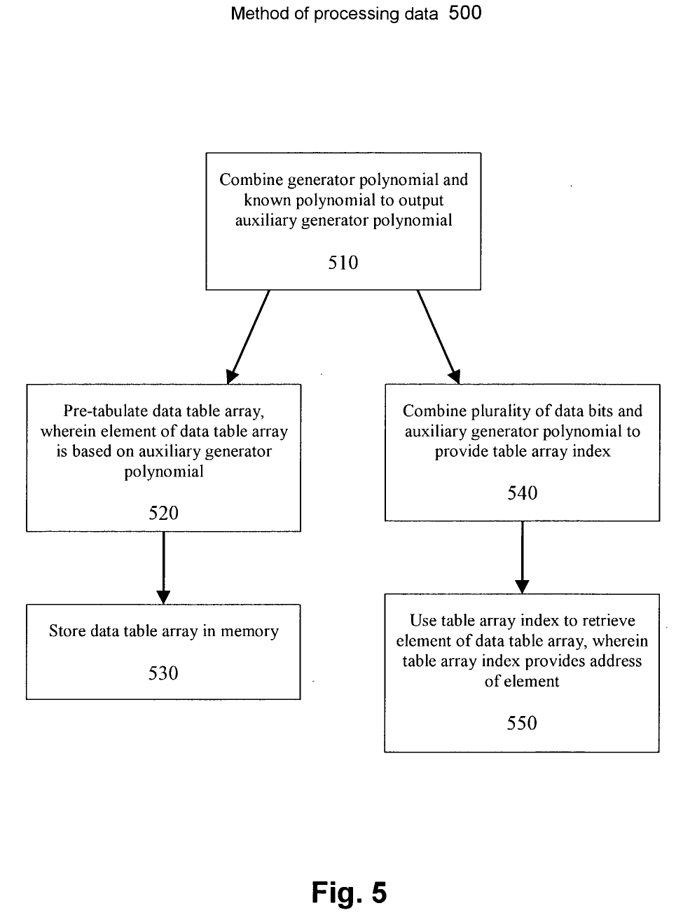

FIG. 5 illustrates a flow chart for a method of processing data according to an embodiment of the present invention. Within the method and referring to FIG. 1, a data table array 130 is pre-tabulated 520. An element of the data table array 130 is based on an auxiliary generator polynomial. The data table array 130 may be stored 530 in a memory 140. A first combiner 120 may combine 510 a generator polynomial and a known polynomial to output the auxiliary generator polynomial. A second combiner 150 may combine 540 a plurality of data bits and the auxiliary generator polynomial to provide a table array index. The table array index is used 550 to retrieve an element of the data table array 130. The table array index indicates an address of the element. The address may represent a location of the element in the memory 140.

According to an embodiment of the present invention, the auxiliary generator polynomial may have an order of a multiple of eight. In an embodiment, a number of possible values of the table array index may be a multiple of eight.

The flow chart of FIG. 5 may be implemented, for example, using a CRC technique, a scrambler technique, and/or a de-scrambler technique. An example of pseudo-code for each technique follows.

1. Partial Pseudo-Code for CRC Processing

The following partial pseudo-code for CRC processing is based on the G.shdsl modem standard, ITU-T G.991.2, pre-published version, February 2001, which “describes a [symmetric digital subscriber line] transmission method for data transport in telecommunications access networks.” ITU-T G.991.2, p. 3. A CRC generator polynomial used, for example, during a data mode may be g(D)D⁶\mathring{+}D\mathring{+}1. The order of g(D) for this example is six, which is not a multiple of eight. However, an auxiliary CRC generator polynomial having an order of a multiple of eight may be generated, such as gₐᵤₓ(D)=D⁸\mathring{+}D⁶\mathring{+}D³\mathring{+}D²\mathring{+}D\mathring{+}1.

% TableLookUpArray, in this example, is a pre-tabulated data table array of total 256 % bytes corresponding to gₐᵤₓ(D), where a byte is eight bits. TableLookUpArray % may be pre-computed on-line and saved during power-on of a modem.

CRC_Input=CRC_Input(:);

% CRC_Input is the original CRC input bit-stream, also referred to as a plurality of data % bits, implemented as a column-wise vector.

L=length(CRC_Input);

% L is the total number of bits of the CRC input bit-stream. In this example, the % variable, Bnew, holds eight bits of the CRC input bit-stream at a time.

CRC_aux=[CRC_input0(L−1); CRC_input0(L)];

% CRC_aux includes the last two bits of the original CRC input bit-stream.

CRC_output=zeros(n, 1);

% Assuming for this example that n=8, CRC_output is 8 bits, and the auxiliary generator % polynomial is gₐᵤₓ(D)=D⁸+D⁶+D³+D²+D+1. CRC_output will ultimately hold % the final CRC output, which is six bits in this example. The value of n need not equal % 8 and may be any suitable value. For example, if n=4, then TableLookUpArray may % occupy 16 memory spaces, but the CRC calculation process may require more MIPs %o usage. For example, if n=12, then TableLookUpArray may occupy 4096 memory % spaces, but the CRC calculation process may require less MIPs usage.

Bx2=zeros(n, 1);

% Assuming for this example that n=8, Bx1 and Bx2 are each eight bits in length, while % Bnew holds eight bits at a time from the CRC input bit-stream.

for ii=1:L/n

% This begins a for-loop, each iteration of which will process n-bits of the CRC input % bit-stream. For example, if n=8, then the loop will process one byte of the CRC % input bit-stream at a time, where one byte equals eight bits.

Bx1=xor(Bnew>>2, Bx2);

% Bnew>>2 indicates that Bnew is being shifted two bits to the right, the result % being combined with Bx2 by an exclusive-or logical operation.

Baux=xor(CRC_output, Bx1);

% CRC output is combined with Bx1 by an exclusive-or operation. Baux % is updated with each update of Bnew.

CRC_output=TableLookUpArray(Baux);

% Baux functions as a table array index that indicates an address of an element % of the data table array. The data table array is referenced in this example as % TableLookUpArray.

Bx2=Bnew<<6;

% Bnew<<6 indicates that Bnew is being shifted six bits to the left.

end

% This ends the for-loop.

% The final stage may not be needed. However, in this example, CRC_output is an % eight-bit variable; whereas, the final CRC output should be six bits. Thus, the final % stage is needed to modify the variable, CRC_output, to achieve a CRC output of six % bits. In this example, if L, the total number of bits of the CRC input bit-stream, is a % multiple of 8, the final stage should be implemented as follows. However, if L is not % a multiple of 8, the following should be modified. For example, if the remainder of L % divided by 8 is 6, the the first two lines of the following implementation need not be % performed.

CRC_output(8)=xor(CRC_output(8), CRC_aux(1));

CRC_output(7)=xor(CRC_output(7), CRC_aux(2)),

Final_CRC_Output(1:2)=CRC_output(1:2);

Final_CRC_Output(3:4)=xor(CRC_output(5:6), CRC_output(7:8));

Final_CRC_Output(5:6)=CRC_output(7:8);

% The final CRC output is Final_CRC_Output(1:6).

In this example, if the total number of bits of the CRC input bit-stream, L, is not a multiple of eight, then an appropriate number of zeros may be appended to the CRC input bit-stream to achieve a length of a multiple of eight. However, L need not be a multiple of eight. In other words, an embodiment of the present invention does not require that the total number of bits of the CRC input bit-stream be a multiple of eight. For example, the partial pseudo-code may be implemented to process four bits of the CRC input bit-stream at a time. A nibble may be defined to be four bits. Thus, nibbleby-nibble processing may be defined to mean that four bits are processed at a time. If the CRC input bit-stream is processed nibble-by-nibble, then the number of MIPs needed is doubled, as compared to the situation in which the CRC input bit-stream is processed byte-by-byte, but the memory needed is reduced by a factor of 16.

The preferred number of bits that may be processed at a time may vary, depending on the technology of the device or system that is to incorporate the partial pseudo-code for CRC processing. For example, a silicon chip may be inherently limited in the processing speed at which it may perform operations, or it may be limited in the number of memory spaces that may be placed on the chip. A trade-off may be made between memory space and cycle speed to process the CRC input bit-stream. The cycle speed is typically referenced by the term “million instructions per second” (“MIPs”). In the CRC example above, if “n” is defined as the number of bits of the CRC input bit-stream that are processed at a time, an increase in n generally increases an amount of memory needed to store the pre-tabulated data table array, but decreases a number of MIPs that are needed. On the other hand, if n decreases, then the amount of memory needed to store the pre-tabulated data table array generally decreases, but the number of MIPs that are needed increases. For example, if the CRC input bit-stream is processed word-by-word, i.e., sixteen bits at a time, then the number of MIPs needed is reduced by approximately 50%, as compared to the situation in which the CRC input bit-stream is processed byte-by-byte, but more memory is needed. In this example, the CRC generator polynomial, g(D), and a known polynomial k(D)=(D¹⁰+1) may be combined by performing a polynomial multiplication operation, providing an auxiliary CRC generator polynomial of gₐᵤₓ(D)=g(D)\mathring{×}k(D)=D¹⁶+D¹¹+D¹⁰+D⁶+D+1.

The partial pseudo-code for CRC processing provided above is merely an example of pseudo-code that may be used to implement an embodiment of the present invention. Any suitable pseudo-code may be used.

2. Partial Pseudo-Code for Scrambler Processing

A scrambler device and a de-scrambler device often utilize the following pair of scrambler/de-scrambler generator polynomials: g₁(D)=1+D⁻¹⁸+D⁻²³ and g₂(D)=1+D⁻⁵+D⁻²³. An auxiliary scrambler generator polynomial may be obtained by combining the scrambler generator polynomial with a first known polynomial. Similarly, an auxiliary de-scrambler generator polynomial may be obtained by combining the de-scrambler generator polynomial with a second known polynomial. Although, in the example below, the first known polynomial and the second known polynomial are same, the first known polynomial and the second known polynomial may be different. For example, the first known polynomial may be represented as k(D)=(1+D⁹)D²³, resulting in an auxiliary scrambler generator polynomial of gₐᵤₓ₁(D)=g₁(D)\mathring{×}k(D)=1+D⁵+D⁹+D¹⁴+D²³ +D³² and an auxiliary de-scrambler generator polynomial of gₐᵤₓ₂(D)=g₂(D)\mathring{×}k(D)=1+D⁹+D¹⁸+D²³+D²⁷+D³² in this example. The following partial pseudo-code for the scrambler device represents one implementation of an embodiment of the present invention.

% TableLookUpArray1 and TableLookUpArray2, in this example, are pre-tabulated data % table arrays. The first data table array may comprise 256 bytes, and the second data % table array may comprise 256 double-words, where a double-word is thirty-two bits. % TableLookUpArray1 and TableLookUpArray2 may be pre-computed on-line and % saved during initial modem power-on.

SC_aux0=zeros(1, 32); SC_aux=zeros(1, 32);

% SC_aux0 and SC_aux are initialized.

for I=1:L/n

% This begins a for-loop, each iteration of which will process n-bits of the scrambler % input bit-stream. In this example, n=8. Thus, the loop will process one byte of the % scrambler input bit-stream at a time, where one byte equals eight bits. The value of n % need not equal 8 and may be any suitable value. For example, if n=4, then % TableLookUpArray1 and TableLookUpArray2 may occupy fewer memory spaces, % as compared to the situation in which n=8, but the scrambler process may require % more MIPs usage. For example, if n=12, then TableLookUpArray1 and % TableLookUpArray2 may occupy more memory spaces, as compared to the situation % in which n=8, but the scrambler process may require less MIPs usage.

Baux=xor(SC_aux(25:32), Bnew);

% SC_aux, an auxiliary generator polynomial, is combined with Bnew, a segment % of the scrambler input bit-stream, by an exclusive-or operation. Baux is % updated with each update of Bnew.

SC_Output(i)=TableLookUpArray1 (Baux);

% Baux functions as a table array index that indicates an address of an element % of a data table array, referenced in this example as TableLookUpArray1.

SC_aux=TableLookUpArray2(Baux);

% Baux functions as a table array index that indicates an address of an element % of a data table array, referenced in this example as TableLookUpArray2.

SC_aux(9:32)=xor(SC_aux0(9:32), SC_aux(1:24));

% In this example, an exclusive-or logical operation is used to update SC_aux.

SC_aux0=SC_aux;

% SC_aux0 is updated.

end

% This ends the loop.

% The remarks that were made as to the partial pseudo-code for CRC processing may % also apply to the partial pseudo-code for scrambler processing.

The partial pseudo-code for scrambler processing provided above is merely an example of pseudo-code that may be used to implement an embodiment of the present invention. Any suitable pseudo-code may be used. The remarks following the Partial Pseudo-code for CRC Processing may also apply to the Partial Pseudo-code for Scrambler Processing.

3. Partial Pseudo-Code for De-scrambler Processing

The following partial pseudo-code for de-scrambler processing represents one implementation of an embodiment of the present invention.

% TableLookUpArray, in this example, is a pre-tabulated data table array. The data % table array may consist of total 256 double words. TableLookUpArray may be % pre-computed on-line and saved during initial modem power-on.

L=length(DS_Input);

% L is the total number of bits of the de-scrambler input bit-stream. In this example, the % variable, Bnew, holds n bits of the de-scrambler input bit-stream at a time.

for i=1:L/n

% This begins a for-loop, each iteration of which will process n-bits of the de-scrambler % input bit-stream. In this example, n=8. Thus, the loop will process one byte of the % de-scrambler input bit-stream at a time, where one byte equals eight bits. The value % of n need not equal 8 and may be any suitable value. For example, if n=4, then % TableLookUpArray1 and TableLookUpArray2 may occupy fewer memory spaces, % as compared to the situation in which n=8, but the de-scrambler process may require % more MIPs usage. For example, if n=12, then TableLookUpArray1 and % TableLookUpArray2 may occupy more memory spaces, as compared to the situation % in which n=8, but the de-scrambler process may require less MIPs usage.

DSaux0=TableLookUpArray(Bnew);

% Bnew functions as a table array index that indicates an address of an element % of a data table array, referenced in this example as TableLookUpArray.

DS_aux=xor(Dsaux0, DS_aux);

% In this example, an exclusive-or logical operation is used to update DS_aux.

DS_Output(i)=DS_aux(25:32);

% The de-scrambler device outputs a byte of data.

DS_aux=[zeros(1, 8) DS_aux(1:24)];

% DS_aux is updated.

end

% This ends the loop.

% The remarks that were made as to the partial pseudo-code for CRC processing may % also apply to the partial pseudo-code for de-scrambler processing.

The partial pseudo-code for de-scrambler processing provided above is merely an example of pseudo-code that may be used to implement an embodiment of the present invention. Any suitable pseudo-code may be used. The remarks following the Partial Pseudo-code for CRC Processing may also apply to the Partial Pseudo-code for De-scrambler Processing.

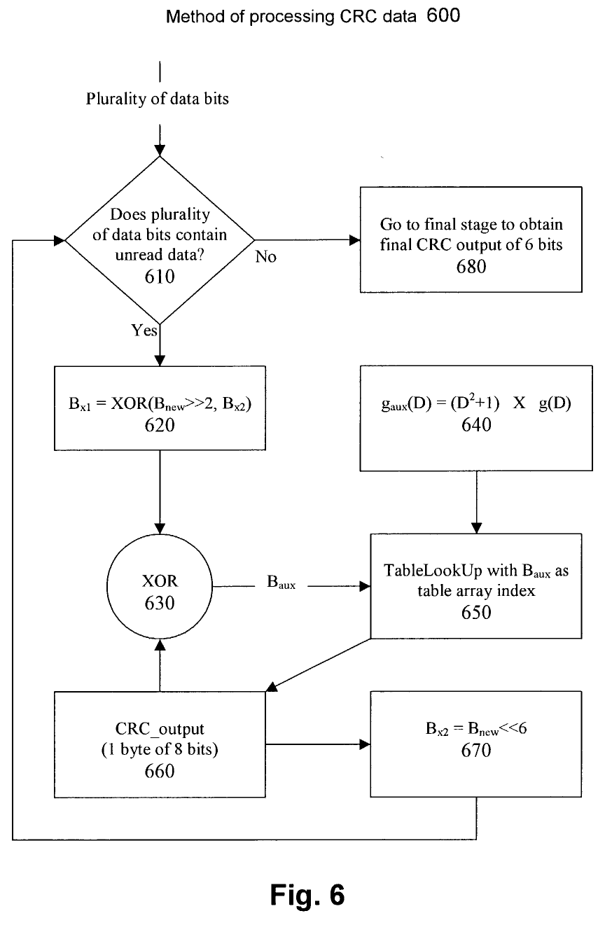

FIG. 6 illustrates a flow chart for a method of processing CRC data according to an embodiment of the present invention. The flow chart of FIG. 6 provides a pictorial representation of the partial pseudo-code for CRC processing provided in the example of item 1 above, assuming that the CRC input bit-stream is not processed six bits at a time. Otherwise, item 680, “Go to final stage to obtain final CRC output of 6 bits,” would not be necessary for this example.

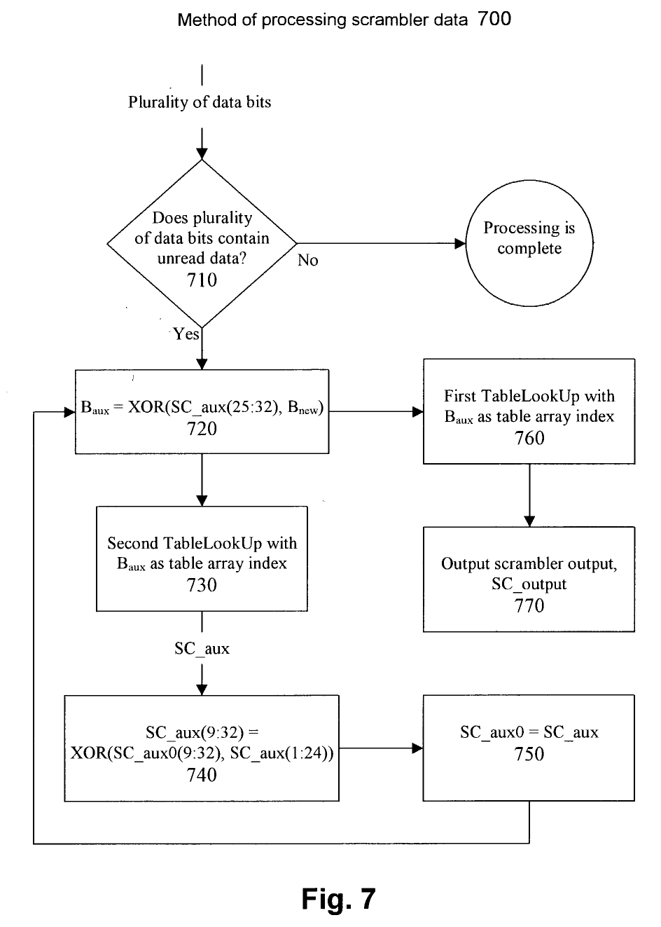

FIG. 7 illustrates a flow chart for a method of processing scrambler data according to an embodiment of the present invention. The flow chart of FIG. 7 provides a pictorial representation of the partial pseudo-code for scrambler processing provided in the example of item 2 above.

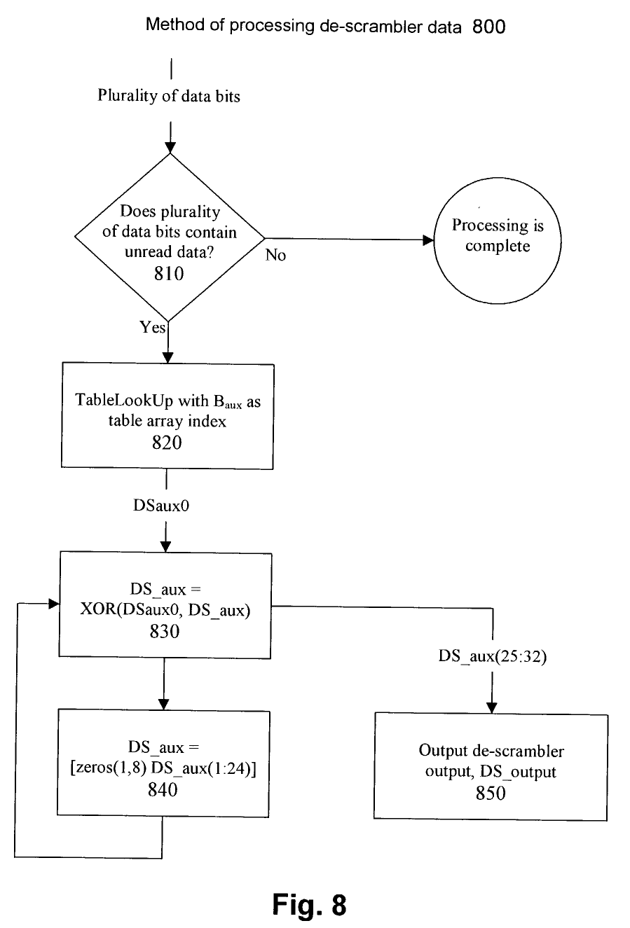

FIG. 8 illustrates a flow chart for a method of processing de-scrambler data according to an embodiment of the present invention. The flow chart of FIG. 8 provides a pictorial representation of the partial pseudo-code for de-scrambler processing provided in the example of item 3 above.

The table-lookup device 100 according to an embodiment of the present invention allows the order of a generator polynomial to be any integer; whereas, conventional table-lookup devices require that the order of the generator polynomial be a multiple of eight. Furthermore, an embodiment of the present invention may apply to cyclic redundancy check (“CRC”), scrambler, and de-scrambler techniques, for example. In addition, an embodiment of the present invention may allow CRC, scrambler, and de-scrambler operations to be performed byte-by-byte. Thus, digital signal processor (“DSP”) computational complexity, for example, may be reduced by approximately a factor of eight, as compared to conventional bit-by-bit processing devices, such as CRC devices, scrambler devices, and de-scrambler devices.

While the description above refers to particular embodiments of the present invention, it will be understood that many modifications may be made without departing from the spirit thereof. The accompanying claims are intended to cover such modifications as would fall within the true scope and spirit of an embodiment of the present invention. The presently disclosed embodiments are therefore to be considered in all respects as illustrative and not restrictive, the scope of an embodiment of the invention being indicated by the appended claims, rather than the foregoing description, and all changes that come within the meaning and range of equivalency of the claims are therefore intended to be embraced therein.

What is claimed is:

1. A table-lookup device, comprising:
an input to receive a plurality of data bits;
a first combiner to combine a generator polynomial and a known polynomial and to provide an auxiliary generator polynomial;
a data table array, wherein the data table array is based on the auxiliary generator polynomial;
a memory to store the data table array; and
a second combiner to combine the plurality of data bits and the auxiliary generator polynomial and to provide a table array index, wherein the table array index indicates an address of an element of the data table array.

2. The table-lookup device according to claim 1, wherein the first combiner and the second combiner are a single device.

3. The table-lookup device according to claim 1, wherein the table-lookup device is a cyclic redundancy check (“CRC”) device.

4. The table-lookup device according to claim 1, wherein the table-lookup device is a scrambler device.

5. The table-lookup device according to claim 1, wherein the table-lookup device is a de-scrambler device.

6. The table-lookup device according to claim 1, wherein the auxiliary generator polynomial has an order of a multiple of eight.

7. The table-lookup device according to claim 1, wherein a number of possible values of the table array index is a multiple of eight.

8. A communication device, comprising:
a source to provide input data bits;
a table-lookup device to receive the input data bits, including
an input to receive a plurality of data bits,
a first combiner to combine a generator polynomial and a known polynomial and to provide an auxiliary generator polynomial,
a data table array, wherein the data table array is based on the auxiliary generator polynomial,
a memory to store the data table array, and
a second combiner to combine the plurality of data bits and the auxiliary generator polynomial and to provide a table array index, wherein the table array index indicates an address of an element of the data table array; and
a modulator to modulate a symbol that is based on an output of the table-lookup device.

9. The communication device according to claim 8, wherein the first combiner and the second combiner are a single device.

10. The communication device according to claim 8, wherein the table-lookup device is a cyclic redundancy check (“CRC”) device.

11. The communication device according to claim 8, wherein the table-lookup device is a scrambler device.

12. The communication device according to claim 8, wherein the communication device is a transmitter.

13. A communication device, comprising:
a de-modulator to de-modulate a received symbol;
a table-lookup device to receive input data bits, including
an input to receive a plurality of data bits,
a first combiner to combine a generator polynomial and a known polynomial and to provide an auxiliary generator polynomial,
a data table array, wherein the data table array is based on the auxiliary generator polynomial,
a memory to store the data table array, and
a second combiner to combine the plurality of data bits and the auxiliary generator polynomial and to provide a table array index, wherein
the table array index indicates an address of an element of the data table array; and
a sink to store a stream of data bits.

14. The communication device according to claim 13, wherein the first combiner and the second combiner are a single device.

15. The communication device according to claim 13, wherein the table-lookup device is a cyclic redundancy check (“CRC”) device.

16. The communication device according to claim 13, wherein the table-lookup device is a de-scrambler device.

17. The communication device according to claim 13, wherein the communication device is a receiver.

18. A communication system, comprising:
a transmitter, including
a source to provide input data bits,
a first data-lookup device to provide a first auxiliary generator polynomial and to provide a first table array index based on the first auxiliary generator polynomial, wherein the first table array index indicates a first address of a first element of a first data table array, and
a modulator to modulate a symbol that is based on an output of the first table-lookup device;
a communication channel to receive an output of the modulator; and
a receiver to receive an output of the communication channel, including
a de-modulator to de-modulate a received symbol,
a second table-lookup device to provide a second auxiliary generator polynomial and to provide a second table array index based on the second auxiliary generator polynomial, wherein the second table array index indicates a second address of a second element of a second data table array, and
a sink to store a stream of data bits.

19. The communication system according to claim 18, wherein the first table-lookup device includes:
an input to receive a plurality of data bits;
a first combiner to combine a generator polynomial and a known polynomial and to provide the first auxiliary generator polynomial;
a memory to store the first data table array; and
a second combiner to combine the plurality of data bits and the first auxiliary generator polynomial and to provide the first table array index.

20. The communication system according to claim 18, wherein the second table-lookup device includes:
an input to receive a plurality of data bits;
a first combiner to combine a generator polynomial and a known polynomial and to provide the second auxiliary generator polynomial;
a memory to store the second data table array; and
a second combiner to combine the plurality of data bits and the second auxiliary generator polynomial and to provide the second table array index.

21. The communication system according to claim 18, wherein the communication system is a modem.

22. The communication system according to claim 18, wherein the communication system is a networking system.

23. The communication system according to claim 18, wherein the first table-lookup device is a cyclic redundancy check (“CRC”) device.

24. The communication system according to claim 18, wherein the first table-lookup device is a scrambler device.

25. The communication system according to claim 18 wherein the second table-lookup device is a cyclic redundancy check (“CRC”) device.

26. The communication system according to claim 18 wherein the second table-lookup device is a de-scrambler device.

27. A method of processing data, comprising:
pre-tabulating a data table array, wherein an element of the data table array is based on an auxiliary generator polynomial;
storing the data table array in a memory;
combining a generator polynomial and a known polynomial to output the auxiliary generator polynomial;
combining a plurality of data bits and the auxiliary generator polynomial to provide a table array index; and
using the table array index to retrieve the element of the data table array, wherein the table array index indicates an address of the element.

28. The method according to claim 27, wherein the auxiliary generator polynomial has an order of a multiple of eight.

29. The method according to claim 27, wherein a number of possible values of the table array index is a multiple of eight.

30. An article comprising:
a storage medium having stored thereon instructions that when executed by a machine result in the following:
pre-tabulating a data table array, wherein an element of the data table array is based on an auxiliary generator polynomial,
storing the data table array in a memory,
combining a generator polynomial and a known polynomial to output the auxiliary generator polynomial,
combining a plurality of data bits and the auxiliary generator polynomial to provide a table array index, and
using the table array index to retrieve the element of the data table array, wherein the table array index indicates an address of the element.

31. The article according to claim 30, wherein the auxiliary generator polynomial has an order of a multiple of eight.

32. The article according to claim 30, wherein a number of possible values of the table array index is a multiple of eight.
